(19) United States
(12) Patent Application Publication
(10) Pub. No.: US 2004/0075160 A1
(43) Pub. Date: Apr. 22, 2004

(54) Transient voltage suppressor having an epitaxial layer for higher avalanche voltage operation

(76) Inventors: Jack Eng, Valley Stream, NY (US); John Naughton, Blarney (IE); Lawrence Laterza, Miller Place, NY (US); James Hayes, Rochestown (IE); Jean-Michel Guillot, Cloyne (IE)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/274,450

(22) Filed: Oct. 18, 2002

(51) Int. Cl. H01L 29/06

(52) U.S. Cl. 257/623

(57) ABSTRACT

A semiconductor device includes a heavily doped first layer of a first conductivity type having a bulk portion and a mesa portion disposed above the bulk portion. A second layer of a second conductivity type is deposited on the mesa portion of the first layer to form a p-n junction therewith. The second layer is more lightly doped than the first layer. A contact layer of the second conductivity type is formed on the second layer. First and second electrodes electrically contact the bulk portion of the first layer and the contact layer, respectively.

### FIELD OF THE INVENTION

The present invention relates generally to transient voltage suppressors (TVS) and more particularly to an Avalanche Breakdown Diode (ABD) for office equipment, lighting ballasts and high intensity discharge lighting, or microprocessor-based equipment.

### BACKGROUND OF THE INVENTION

Communications equipment, computers, home stereo amplifiers, televisions, and other electronic devices are increasingly manufactured using small electronic components which are very vulnerable to damage from electrical energy surges (i.e., transient over-voltages). Surge variations in power and transmission line voltages, can severely damage and/or destroy electronic devices. Moreover, these electronic devices can be very expensive to repair and replace. Therefore, a cost effective way to protect these components from power surges is needed. Devices known as transient voltage suppressors (TVS) have been developed to protect these types of equipment from such power surges or over-voltage transients. These devices, typically discrete devices similar to discrete voltage-reference diodes, are employed to suppress transients of high voltage in a power supply or the like before the transients reach and potentially damage an integrated circuit or similar structure.

In a semiconductor surge suppressor employing a p-n junction, the junction is sometimes formed by diffusing a layer of a given conductivity into a substrate of the opposite conductivity. While such a device is satisfactory for many applications, a number of problems are associated with it. For example, voltage uniformity and power handling capabilities are not always satisfactory. In particular, the breakdown voltage, which is a key customer-specified parameter, may vary substantially from device to device, yielding substantial variations in breakdown voltages that are outside the customer's allowable tolerances. These variations arise because the breakdown voltage occurs in the substrate when the substrate is the high-resistivity region (i.e., low doping concentration) and it is generally difficult to precisely control the resistivity of the substrate and the ingot from which it is obtained. As a result the manufacturing yields of such devices can be relatively low. Moreover, the value of the breakdown voltage that can be achieved may be limited because breakdown tends to occur near the termination region of the junction, causing higher electric fields to arise at the device edge, making device passivation less effective. Another problem arises from the high electric field at the surface, which reduces the breakdown voltage while increasing its variability, and which also increases the leakage current near the breakdown voltage. The value of the voltage-clamping ratio is adversely affected because it is related to the series resistance of the device, which in turn is related to the thickness of the device's high reistivity region (e.g, its N-region). As a consequence the device has a higher than desirable clamping voltage.

### SUMMARY OF THE INVENTION

The present invention provides a semiconductor device that includes a heavily doped first layer of a first conductivity type having a bulk portion and a mesa portion disposed above the bulk portion. A second layer of a second conductivity type is deposited on the mesa portion of the first layer to form a p-n junction therewith. The second layer is more lightly doped than the first layer. A contact layer of the second conductivity type is formed on the second layer. First and second electrodes electrically contact the bulk portion of the first layer and the contact layer, respectively.

In accordance with one aspect of the invention, a passivating layer is formed on a sidewall of the mesa portion.

In accordance with another aspect of the invention, the second layer is deposited by chemical vapor deposition.

In accordance with yet another aspect of the invention, the mesa portion is tapered with a positive bevel angle.

### BACKGROUND OF THE INVENTION

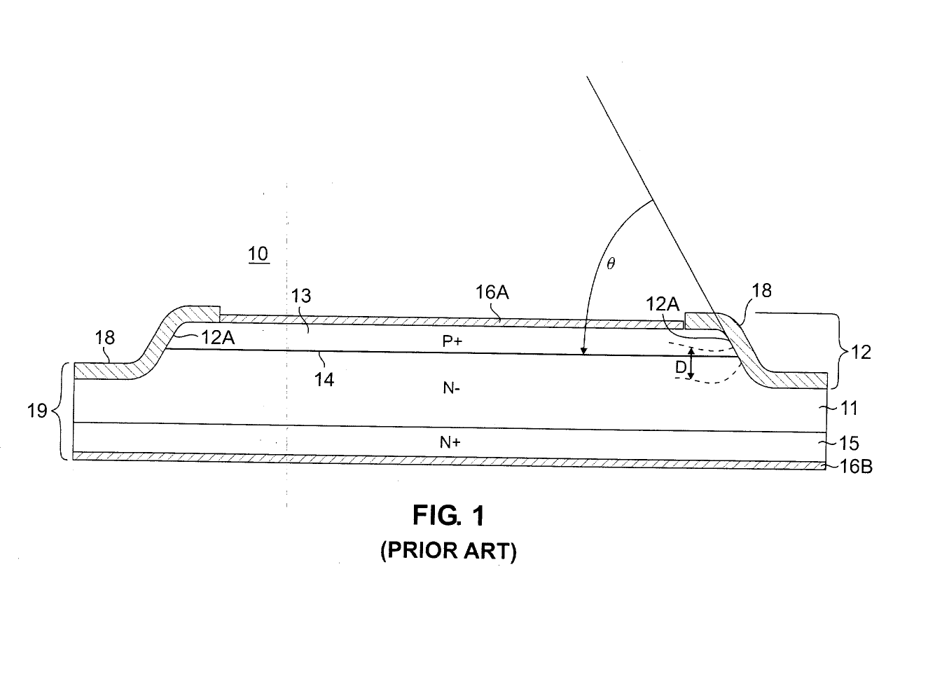

FIG. 1 shows a cross-section of a conventional silicon diode chip that may be used as a transient voltage suppressor.

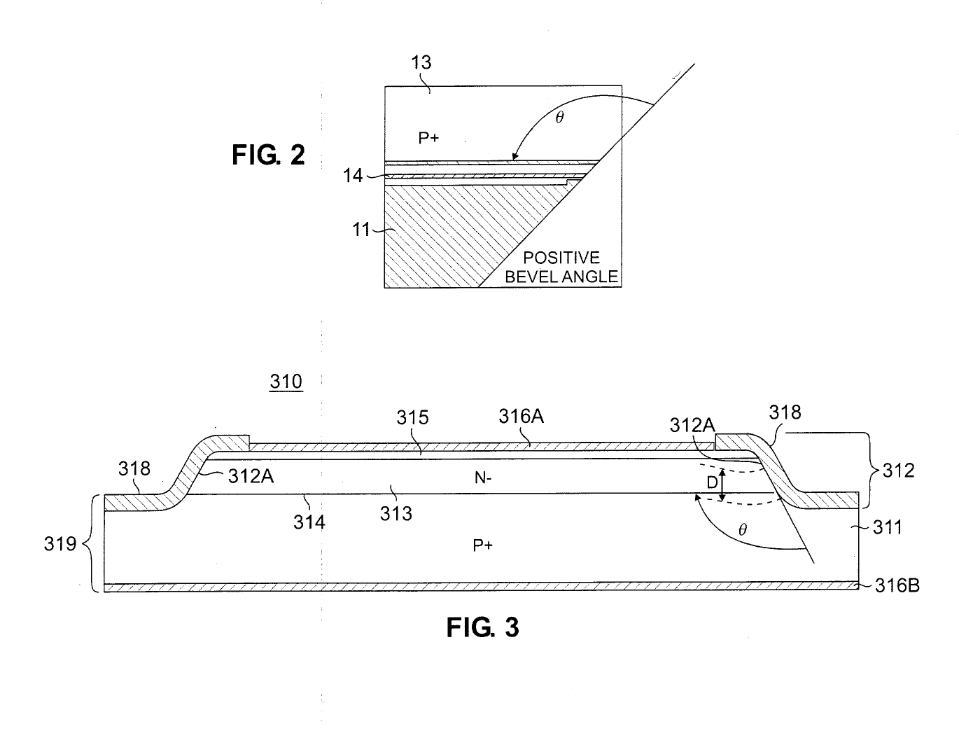

FIG. 2 shows the termination region of a silicon diode chip for the same layer structure seen in FIG. 1 but with a positive bevel angle.

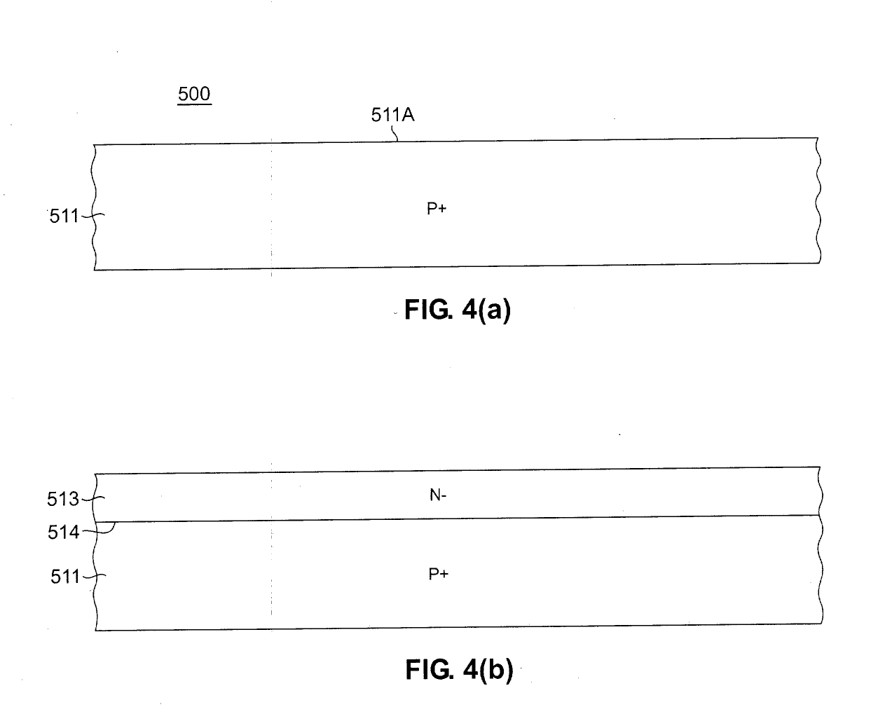

FIG. 3 shows a cross-section of silicon diode chip constructed in accordance with the present invention.

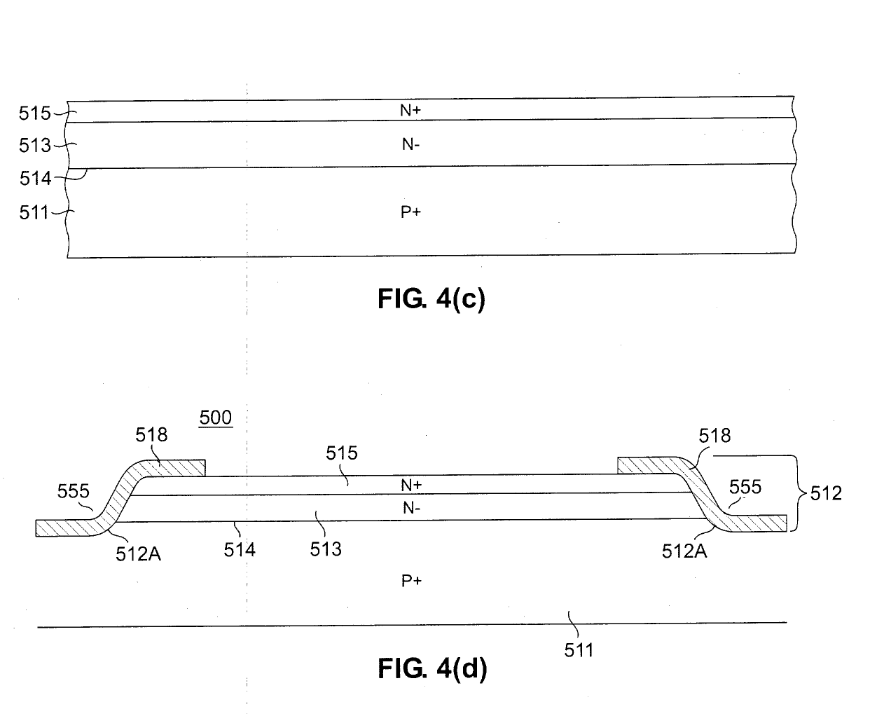

FIGS. 4(a)-4(d) show a series of process steps that may be employed to produce the silicon diode chip shown in FIG. 3.

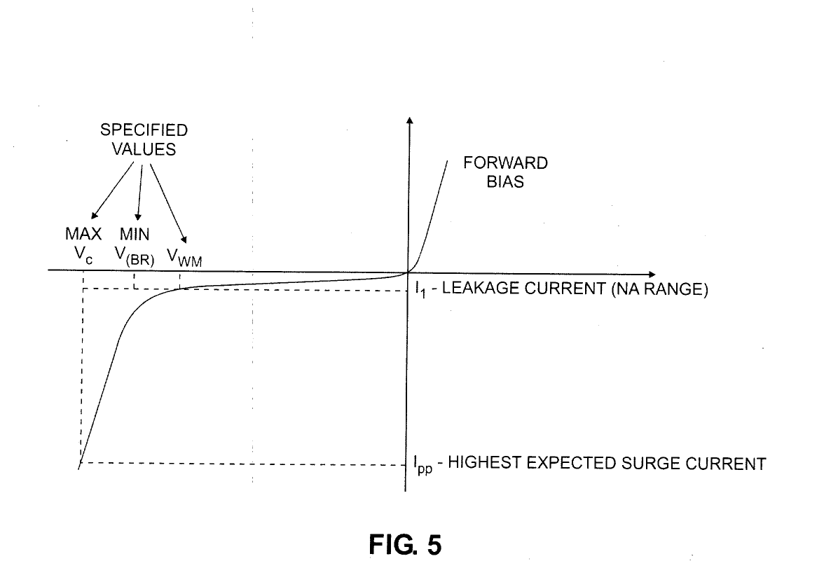

FIG. 5 shows a current-voltage curve for a voltage suppressor such as shown in FIG. 3.

### DETAILED DESCRIPTION

Referring now to FIG. 1, there is shown a prior art silicon diode formed on a silicon chip 10. The device is often employed as a transient voltage suppressor. In manufacture, the starting wafer typically is large enough to accommodate many such chips, and many chips are processed in parallel in each wafer. The wafer is subsequently cut up to form individual dice or chips, each housing one or more diode devices. In most respects, it will be convenient to describe the invention as though a single device is being made in each wafer.

The silicon chip 10 includes a bulk portion or substrate 11 that forms the bulk of the chip 10. It typically is of relatively high resistivity material, either n− type or p− type conductivity. In FIG. 1, bulk portion 11 is of n− type conductivity. As is known, the resistivity of this high-resistivity bulk portion 11 largely determines the breakdown voltage of the diode, the higher the resistivity, the higher the breakdown voltage (assuming the bulk portion 11 is wide enough to sustain the voltage). The chip 10 includes a mesa portion 12 on which is formed a diffused top layer 13 that is heavily doped and of the opposite conductivity type than that of the bulk portion 11. That is, in FIG. 1, the conductivity of top layer 13 is p+ type. The edges of the mesa 12 are defined by tapered sidewalls 12A. The top layer 13 and bulk portion 11 form a rectifying p-n junction 14 that extends to the sidewall 12A of the mesa. A bottom surface of the chip typically includes a contact layer 15 that is of the same conductivity type but of lower resistivity than the bulk portion 11. Similar to diffused top layer 13, contact layer 15 is formed by diffusion of the appropriate dopant into substrate 11. The contact layer 15 facilitates making a low resistance ohmic connection to the bulk portion 11. Conductive layers, typically of a metal, provide electrode connections 16A and 16B to the opposed diffused layers 13 and 15, respectively. A passivating layer 18 of one or more dielectrics extends along the side wall of the mesa portion and generally partly over the edges of a top surface of layer 13 to reduce edge-breakdown effects. The sidewall 12A of mesa 12 is tapered to facilitate coverage by the passivating layer 18. Typically, the individual chips are separated from the wafer by dicing midway in the moat, leaving a peripheral rim portion 19 to each chip that is thinner than the rest of the chip.

The mesa structure depicted in FIG. 1 is a popular means for providing the device with an appropriate edge termination region for a number of reasons. It is a relatively simple process that results in low manufacturing costs and is easy to passivate. One problem with this structure, however, is that when the breakdown voltage of the device is reached, breakdown tends to occur near the device edge rather than in the bulk. Breakdown in the bulk is preferable to breakdown at the edge of the device since there are less defects in the bulk than at the surface and thus when it occurs in the bulk breakdown will be more stable and predictable and will allow the device to be more easily passivated and it can handle more energy. Another problem with the structure depicted in FIG. 1 is that the high resistivity region is much wider that required to sustain the reverse voltage, which adds needlessly to the value of the series resistance and thus the clamping voltage V_{c}.

The present inventors have recognized that whether breakdown arises at the edge or in the bulk of the device depends in part on the so-called bevel angle of the mesa sidewall. Before further elucidating the relationship between the bevel angle and the location at which breakdown occurs, the bevel angle will be defined with reference to FIGS. 1 and 2. As used herein, the bevel angle refers to the angle between the bevel and the horizontal and which traverses the more heavily doped (in magnitude, regardless of sign) one of the regions 11 and 13 forming the p-n junction. A bevel angle of 90 degrees or less is denoted as a negative bevel angle while a bevel angle greater than 90 degrees is denoted as a positive bevel angle. For example, since in FIG. 1 top layer 13 is more heavily doped than region 11, the bevel angle [symbol] is shown to traverse top layer 13. Moreover, since it is less than 90 degrees, the bevel angle is negative. FIG. 2, on the other hand, shows the termination region of a silicon chip for the same layer structure seen in FIG. 1 but in which the bevel angle is positive.

The present invention may now be more fully described with the bevel angle defined in the aforementioned manner. Specifically, the inventors have determined that breakdown will generally occur at the edge of the device if the bevel angle is negative, whereas breakdown will occur in the bulk if the bevel angle is positive. That is, bulk breakdown will arise in the structure shown in FIG. 2 while breakdown will arise at the edge of the structure shown in FIG. 1. For this reason, the structure shown in FIG. 2 is preferable to the structure shown in FIG. 1.

Breakdown is more likely to occur in the bulk if the bevel angle is positive because the charge in the depletion region on one side of the junction must balance the charge on the other side of the junction. In order to accomplish this, the depletion region in the high-resistivity region bends toward the junction with a negative bevel angle and bends away from the junction with a positive bevel angle (compare the depletion regions D depicted in FIGS. 1 and 3). As a result of this bending, the depletion region near the edge is wider for a positive bevel angle. Since most of the voltage arises in the depletion region, for a given voltage the peak electric field will be lower where the depletion region is wider (since E=V/W, where V=Voltage, W=depletion region width). Therefore, the critical electric field will be reached sooner in the bulk when the bevel angle is positive.

Unfortunately, the slope of the bevel shown in FIG. 2 is difficult to fabricate in practice because the bevel is typically formed by an etchant process that more naturally gives rise to the bevel seen in FIG. 1. Also, it is more difficult to obtain proper passivation coverage with the configuration in FIG. 2. Ideally therefore, the silicon chip should have a bevel that slopes as in FIG. 1 but which has a positive bevel angle as in FIG. 2. As detailed below, the present inventors have developed a structure and a method of forming the structure that meets this requirement.

FIG. 3 shows a silicon chip 310 in accordance with the present invention. The chip 300 includes a p+ type bulk portion or substrate 311, an n− type top layer 313 formed on mesa portion 312, and an n+ type contact layer 315 disposed over top layer 313. The chip 300 advantageously has a mesa sidewall with a positive bevel angle that can be readily formed by an etchant process. This structure differs from that shown in FIG. 1 in that the substrate 311 is now more heavily doped in magnitude than top layer 313 and in that the conductivities are reversed with respect to FIG. 1. As a result, since the bevel angle between the mesa sidewall 312A and the horizontal which traverses the heavily doped substrate is obtuse, the bevel angle is positive.

As previously mentioned, top layer 13 seen in the prior art device of FIG. 1 is typically formed by diffusing the appropriate dopant into the substrate 11. As those of ordinary skill in the art will recognize, when diffusing a layer of a given conductivity into a substrate of the opposite conductivity, the substrate generally should not be heavily doped because the large amount of dopant required to compensate for the heavily doped substrate cannot be readily accommodated in the substrate lattice. For this reason fabrication of the silicon chip generally begins with a lightly doped substrate (regardless of conductivity) so that the diffused top surface layer 13 can be more easily diffused into it. Because the inventive silicon chip shown in FIG. 3 employs a heavily doped substrate, however, it is difficult to fabricate by a diffusion process for the aforementioned reason. Accordingly, the present invention requires a different fabrication process.

The process for forming the inventive silicon chip will now be described with reference to FIGS. 4(a)-4(d), which show the silicon chip 500 in various stages of its manufacture.

FIG. 4(a) illustrates a portion of a starting wafer 511 in which a single chip 500 of the type shown in FIG. 3 is formed. For the typical application the starting material is of relatively heavily doped monocrystalline silicon, either n+ or p+ type conductivity. For purposes of illustration, wafer 511 is assumed to be of p+ type conductivity.

In FIG. 4(b) an epitaxial n− type surface layer 513 is grown on the top surface of starting wafer 511 to form a rectifying p-n junction 514. Epitaxial surface layer 513 may be grown by any technique known to those of ordinary skill in the art, including but not limited to chemical vapor deposition or the like. In FIG. 4(c) n+ type contact layer 515 is formed by diffusion of the appropriate dopant into epitaxial layer 513. Alternatively, contact layer 515 may be formed by deposition of an additional epitaxial layer onto epitaxial layer 513.

FIG. 4(d) shows the chip 500 after there has been formed the moat (or trench) 555 that defines a central mesa 512, within which is included rectifying junction 514. Mesa 512 terminates on sidewalls 512A defined by the moat 555. Advantageously, the moat 555 is etched, usually isotropically, with a wet etch to form sidewalls 512A of the mesa 512. As mentioned previously, the sloping of the sidewalls promotes good coverage of any layers deposited thereover. The moat 555 is localized in the usual fashion by photoresist masking regions not to be etched, before the chip 500 is exposed to the wet etchant. The depth of the moat needs to be sufficient so that the junction 514 terminates on the sidewall 512A of the mesa 512, as is shown.

A passivating layer 518 of one or more dielectrics extends along the sidewalls 512A of the mesa 512 and generally over the edges of contact layer 515. Passivating layer 518 may be formed, for example, from silicon nitride, silicon dioxide, semi-insulating polysilicon, a silicate glass, or a combination thereof. The device is subsequently metallized to provide electrical contacts (not shown) to contact layer 15 and bulk portion 511. If many chips are being made from the wafer, there remains to dice the wafer into individual chips, typically by dicing the wafer at the region of the moat 555 or between adjacent moats. While the wafer is typically diced after passiviation, the present invention also encompasses devices that are diced before passiviation.

Additional details concerning the various processing steps and the dimensions of the various regions are within the purview of one of ordinary in the art and the specifics are dependent on the application to be made of the devices.

In contrast to the prior art silicon chip seen in FIG. 1, the present invention forms top layer 513 by a deposition technique instead of a diffusion technique. This is advantageous because as a result top layer 513 can be formed without regard to the level of dopant in the wafer substrate 511. In particular, because a growth technique is employed, wafer 511 may be heavily doped since when top layer 513 is formed there is no need to diffuse a dopant into wafer 511, which, as previously mentioned, can be difficult to accomplish in a heavily doped wafer. Accordingly, because the wafer 511 can now be heavily doped, a chip with a positive bevel angle as shown in FIGS. 2 and 3 can be readily formed, thus allowing bulk breakdown to arise rather than breakdown at the edge of the device.

The present invention offers a number of advantages when employed as a transient voltage suppressor. The operating characteristics of the inventive voltage suppressor may be described with reference to its current-voltage curve, which is illustrated in FIG. 5. The characteristics of the device are typically specified in terms of the following ratings: V_{WM} (the maximum working voltage), V_{(BR)} (the breakdown voltage), and V_{C} (the clamping voltage) The maximum working voltage V_{WM} denotes the maximum normal operating voltage of the circuit that is to be protected by the voltage suppressor. The breakdown voltage V_{(BR)} denotes the voltage at which the device starts to conduct a substantial current, while the clamping voltage V_{C} denotes the maximum voltage that the device may experience at the maximum rated surge current Ipp. The chosen value of V_{C} should be below the minimum voltage that can damage the circuit being protected.

A figure of merit for the voltage suppressor is the voltage-clamping ratio, which is expressed as the ratio of the clamping voltage V_{C} to the breakdown voltage V_{(BR)}. For a given V_{(BR)}, V_{C} should be as low as possible (but above V_{(BR)})to offer greater voltage protection. While a clamping ratio of unity is ideal, the clamping ratio will in general be greater than one. As will now be explained, the inventive device can achieve a better clamping ratio (i.e., a ratio closer to unity) than the prior art device shown in FIG. 1. It is well-known to those of ordinary skill in the art that the clamping ratio is proportional to the differential resistance of the device's breakdown characteristic. Referring now to the prior art chip depicted in FIG. 1, the resistivity of the chip arises largely from the relatively thick bulk portion of substrate 311. This portion of the substrate is much thicker than required to sustain a reverse voltage because it is not practical to diffuse top layer 13 and since bulk portion 311 has a relatively low dopant concentration because it is doped n− type, it has a relatively large resistivity, thus yielding a relatively high series resistance, thus increasing the slope of the breakdown characteristic and increasing the clamping ratio. On the other hand, in the inventive chip depicted in FIG. 3, the epitaxial layer 313 is the high resistivity region. Since the high-resistivity region in device in FIG. 3 is significantly thinner than the high-resistivity region in FIG. 1, the inventive chip depicted in FIG. 3 will have a lower series resistance, resulting in a lower differential resistance thus yielding a lower clamping ratio that is closer to unity. Moreover, a lower clamping ratio will also improve the manufacturing yield of the device because it provides a greater range in which V_{(BR)} can fall while still allowing the device to satisfy the specified clamping voltage at the rated peak-pulse current Iₚₚ, It should be noted that this is not such an issue for a low-voltage TVS, in which the resistivity of the high-resistivity region is not that high. For this reason the higher cost associated with the use of an epitaxial layer instead of a diffusion layer for the top layer is generally not justified for low-voltage TVSs. For high-voltage (i.e., voltages greater than about 450V) applications the clamping ratio of the prior art structure is unacceptable, thus making the present invention particularly advantageous in this regime. For voltages between about 200V-450V the prior art devices have clamping ratios that may be problematic, but this problem is often compensated for by using a device with a larger chip size.

Another advantage of the inventive voltage suppressor is that it has improved current handling capabilities. This can be seen by recognizing that the peak pulse power Pₚₚ dissipated by the device is equal to the product of the peak pulse current Iₚₚ and the clamping voltage V_{C}. That is,

Pₚₚ=IₚₚV_{C}

The peak pulse power Pₚₚ that the device can dissipate is fixed and is largely determined by its thermal resistance, which is directly related to the surface area of the chip's top and bottom. Moreover, for a given V_{(BR}), the inventive voltage suppressor will have a lower clamping voltage V_{C} because of its improved clamping ratio. Accordingly, since V_{C} is reduced, the peak pulse current Iₚₚ that the device can handle is increased.

The current handling capability of the device is also improved because the p-n junction employs an epitaxial layer that is formed on the substrate instead of a diffused layer. In contrast to the diffused layer employed in the prior art voltage suppressor, the epitaxial layer is more uniform and defect free. Moreover, the breakdown voltage in the present invention occurs mainly in the high-resistivity epitaxial layer rather than in the high-resistivity substrate of the prior art device, which as previously mentioned, has many more defects than the epitaxial layer. Such nonuniformities and defects cause leakage and form “hot spots” at the areas where the defects are located. These “hot spots” cause the diode junction to burn up, which keeps the diode from suppressing transients. The use of a positive bevel angle also improves the surge capabability of the device by preventing surface breakdown, which is where the defect density is highest. A positive bevel angle reduces surface breakdown because the voltage extends over a wider surface so that the electric field (V/W), will not reach its critical value.

In summary, the present invention provides a voltage suppressor that achieves a high breakdown voltage. In particular, by employing an epitaxial layer instead of a diffused layer for the top layer that forms the p-n junction of the device so that a lower resistivity substrate can be employed, breakdown voltages as high as 600V have been demonstrated. In contrast, the prior art device shown in FIG. 1 has been largely limited to breakdown voltages of about 440V and below.

1. A semiconductor device comprising:
a heavily doped first layer of a first conductivity type that includes a bulk portion and a mesa portion disposed above the bulk portion;
a second layer of a second conductivity type deposited on the mesa portion of the first layer to form a p-n junction therewith, said second layer being more lightly doped than the first layer;
a contact layer of the second conductivity type formed on the second layer; and
first and second electrodes electrically contacting the bulk portion of the first layer and the contact layer, respectively.

2. The device of claim 1 further comprising a passivating layer formed on a sidewall of the mesa portion.

3. The device of claim 1 wherein the second layer is deposited by chemical vapor deposition.

4. The device of claim 1 wherein the mesa portion is tapered with a positive bevel angle.

5. The device of claim 1 wherein the second layer is an epitaxial layer.

6. The device of claim 1 wherein a breakdown voltage of the device is at least 440 V.

7. A method of making a semiconductor device, comprising:
providing a heavily doped substrate of a first conductivity type;
growing an epitaxial layer of a second conductivity type on the substrate to form a p-n junction, said epitaxial layer being more lightly doped than the substrate;
forming a contact layer of the second conductivity type on the epitaxial layer;
forming an edge termination region at which the p-n junction terminates.

8. The method of claim 7 wherein the step of forming the edge termination regions include the steps of etching a moat through at least a portion of substrate to define a mesa in which the p-n junction is located.

9. The method of claim 7 wherein the mesa is tapered with a positive bevel angle.
